(19) United States
(12) Patent Application Publication
(10) Pub. No.: US 2018/0131015 A1
(43) Pub. Date: May 10, 2018

(54) Low Temperature Atmospheric Pressure Atomic Layer Deposition (ALD) of Graphene on Stainless Steel Substrates as BPP Coating

(71) Applicant: GM GLOBAL TECHNOLOGY OPERATIONS LLC, DETROIT, MI (US)

(72) Inventors: SMURUTHI KAMEPALLI, ROCHESTER, MI (US); BALASUBRAMANIAN LAKSHMANAN, ROCHESTER HILLS, MI (US)

(21) Appl. No.: 15/863,341

(22) Filed: Jan. 5, 2018

Related U.S. Application Data
(62) Division of application No. 14/735,791, filed on Jun. 10, 2015.

(51) Int. Cl. C23C 16/26; C23C 16/50; C23C 16/455

(52) U.S. Cl. CPC H01M 8/0213; H01M 8/0206; H01M 8/0258; H01M 8/0228; H01M 2008/1095; C23C 16/50; C23C 16/45555; C23C 16/45525; C23C 16/26

(57) ABSTRACT

A flow field plate for a fuel cell includes an electrically conductive substrate at least partially defining a plurality of flow channels. A carbon layer is disposed over the flow field plate. The carbon layer includes graphene, carbon nanotubes, or combinations thereof and has a thickness less than about 10 nanometers. Chemical vapor deposition and atomic layer deposition processes for forming graphene layers on a flow field plate are also described.

### TECHNICAL FIELD

In at least one embodiment, the present invention relates to fuel cell bipolar plates with reduced contact resistances.

### BACKGROUND

Fuel cells are used as an electrical power source in many applications. In particular, fuel cells are proposed for use in automobiles to replace internal combustion engines. A commonly used fuel cell design uses a solid polymer electrolyte (“SPE”) membrane or proton exchange membrane (“PEM”) to provide ion transport between the anode and cathode.

In proton exchange membrane type fuel cells, hydrogen is supplied to the anode as fuel, and oxygen is supplied to the cathode as the oxidant. The oxygen can either be in pure form (O₂) or air (a mixture of O₂ and N₂). PEM fuel cells typically have a membrane electrode assembly (“MEA”) in which a solid polymer membrane has an anode catalyst on one face, and a cathode catalyst on the opposite face. The anode and cathode layers of a typical PEM fuel cell are formed of porous conductive materials, such as woven graphite, graphitized sheets, or carbon paper to enable the fuel to disperse over the surface of the membrane facing the fuel supply electrode. Each electrode has finely divided catalyst particles (for example, platinum particles), supported on carbon particles, to promote oxidation of hydrogen at the anode and reduction of oxygen at the cathode. Protons flow from the anode through the ionically conductive polymer membrane to the cathode where they combine with oxygen to form water, which is discharged from the cell. The MEA is sandwiched between a pair of porous gas diffusion layers (“GDL”), which in turn are sandwiched between a pair of non-porous, electrically conductive elements or plates referred to as flow field plates. The plates function as current collectors for the anode and the cathode, and contain appropriate channels and openings formed therein for distributing the fuel cell's gaseous reactants over the surface of respective anode and cathode catalysts. In order to produce electricity efficiently, the polymer electrolyte membrane of a PEM fuel cell must be thin, chemically stable, proton transmissive, non-electrically conductive and gas impermeable. In typical applications, fuel cells are provided in arrays of many individual fuel cell stacks in order to provide high levels of electrical power.

In order to maximize fuel cell performance, it is desirable to minimize contact resistances. For example, the contact resistance between the flow field plates and the gas diffusion layers should be as low as possible. Prior art methods use a bipolar plate coating consisting of a metal interlayer (Ti or Cr) and conductive amorphous carbon layer deposited by physical vapor deposition (PVD) processes on stainless steel substrates. The current state of the art contact resistance using a carbon coating is about 13-16 mΩcm² at 200 psi. Inherent film non-uniformity is observed due to PVD process being a line of sight deposition technique. Moreover, the PVD processes have an associated high capital cost.

Accordingly, there is a need for improved methods for lowering the contact resistances in fuel cell components.

### SUMMARY

The present invention solves one or more problems of the prior art by providing, in at least one embodiment, a flow field plate for a fuel cell. The flow field plate includes an electrically conductive substrate at least partially defining a plurality of flow channels. A carbon layer is disposed over the flow field plate. The carbon layer includes graphene, carbon nanotubes, or combinations thereof and has a thickness of 1 to 10 nanometers.

In another embodiment, a method for forming the flow field plate set forth above having graphene layers is provided. The method includes a step of contacting an electrically conductive substrate with a vapor of a C₁₋₁₈ hydrocarbon-containing compound at a temperature from 350° C. to about 600° C. to form a carbon layer. The carbon layer includes from 1 to 10 graphene monolayers. The electrically conductive substrate at least partially defines a plurality of gas flow channels. Advantageously, in accordance with this method, the carbon layer can be formed by chemical vapor deposition or atomic layer deposition. Growth of multi-layered graphene and carbon nanotubes on stainless steel substrates by atmospheric pressure CVD and ALD processes at temperatures lower than 400° C. can provide a low cost route to depositing highly conductive, corrosion resistant carbon for application as bipolar plate coating. Moreover, higher growth rates and coverage can be achieved by transition metal catalysts such as Ni, Cu and Ru. The graphene deposition process can be achieved with a range of pressures from less than or equal to 1 torr to atmospheric pressure.

### BRIEF DESCRIPTION OF THE DRAWINGS

FIG. 1 provides a schematic of a fuel cell system including an embodiment of a carbon coated bipolar plate;

FIG. 2 is a schematic cross section of a bipolar plate coated with a graphene layer;

FIG. 3 is a schematic cross section of a bipolar plate coated with a graphene layer and a transition metal catalyst layer;

FIG. 4 provides a schematic illustration for an experimental setup for measuring the contact resistance of graphene coated substrates;

FIG. 5 provides an experimental setup for simulating corrosion in a fuel cell;

FIG. 6 provides a plot of the contact resistance versus the applied load for the reference samples as deposited;

FIG. 7 provides a plot of the contact resistance versus the applied load for the graphene samples as deposited;

FIG. 8 provides a plot of the G peak intensity versus temperature for samples synthesized at different CVD growth temperatures with a quadratic curve fitted to the data set and error bars that indicate one standard deviation within the sample area where the Raman map was acquired;

FIG. 9A provides Raman spectra for a carbon layer grown at 400° C.;

FIG. 9B provides Raman spectra for a carbon layer grown at 425° C.;

FIG. 9C provides Raman spectra for a carbon layer grown at 450° C.;

FIG. 9D provides Raman spectra for a carbon layer grown at 475° C.;

FIG. 9E provides Raman spectra for a carbon layer grown at 500° C.;

FIG. 9F provides Raman spectra for a carbon layer grown at 525° C.;

FIG. 9G provides Raman spectra for a carbon layer grown at 550° C.; and

FIG. 9H provides Raman spectra for a carbon layer grown at 600° C.

### DETAILED DESCRIPTION

Reference will now be made in detail to presently preferred compositions, embodiments and methods of the present invention which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

Throughout this application, where publications are referenced, the disclosures of these publications in their entireties are hereby incorporated by reference into this application to more fully describe the state of the art to which this invention pertains.

### Abbreviations

“CVD” means chemical vapor deposition.

“EDX” means energy-dispersive X-ray spectroscopy.

“GDL” means gas diffusion layer.

“PEM” means proton exchange membrane.

“sccm” means standard cubic centimeters per minute.

“SEM” means scanning electron microscopy.

“SS” means stainless steel.

“slpm” means standard liters per minute.

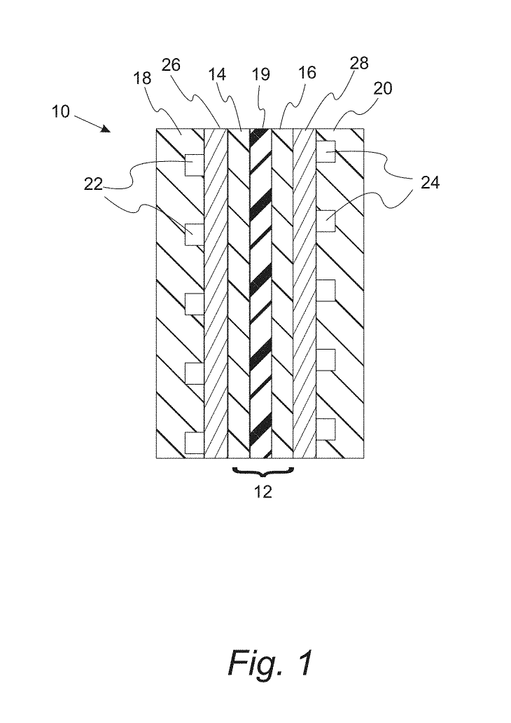

With reference to FIG. 1, a schematic cross section of a fuel cell that incorporates an embodiment of a grafted porous membrane is provided. Proton exchange membrane fuel cell 10 includes polymeric ion conducting membrane 19 disposed between cathode catalyst layer 14 and anode catalyst layer 16. Collectively, the combination of the ion conducting membrane 19, cathode catalyst layer 14 and anode catalyst layer 16 are a membrane electrode assembly. Fuel cell 10 also includes flow field plates 18, 20, gas channels 22 and 24, and gas diffusion layers 26 and 28. In a refinement, flow field plates 18, 20 are bipolar plates. Typically, flow field plates are electrically conductive and are therefore formed from a metal such as stainless steel. In other refinements, the flow field plates include an electrically conductive polymer. Advantageously, flow field plates 18, 20 are coated with a carbon coating, and in particular, a graphene-containing or carbon nanotube-containing layer coating as set forth below in more detail. Hydrogen ions are generated by anode catalyst layer 16 which migrate through polymeric ion conducting membrane 20 where they react at cathode catalyst layer 14 to form water. This electrochemical process generates an electric current through a load connected to flow field plates 18 and 20.

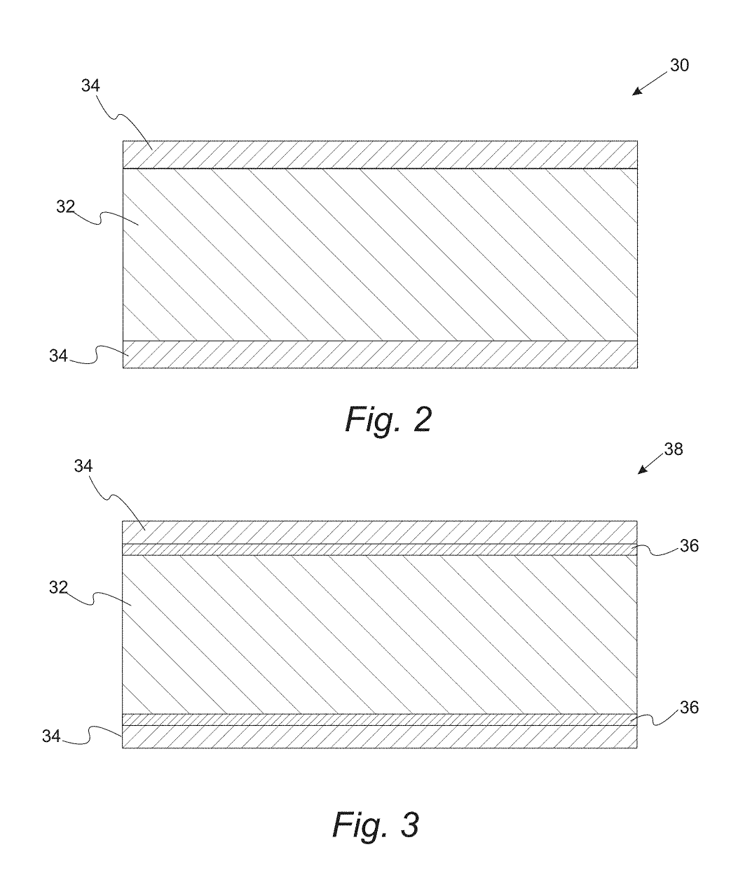

With reference to FIGS. 2 and 3, schematic cross sections of a bipolar plate coated with a graphene layer are provided. Advantageously, the bipolar plates of FIGS. 2 and 3 are incorporated into a fuel cell. FIG. 1 provides a variation in which an electrically conductive substrate is contacted with a carbon coating. Coated substrate 30 includes substrate 32 which is coated with carbon layer 34 which includes one or more graphene monolayers or carbon nanotubes. In one refinement, the carbon layer is a multilayer graphene layer. In a further refinement, the carbon layer includes from 1 to 10 monolayers of graphene. Graphene is a flat single layer of sp² bonded carbon tightly packed into a 2D honeycomb lattice which is the basis for C-60, bucky balls, carbon nanotubes and graphite. In a refinement, substrate 32 is a fuel cell bipolar plate, the surfaces of which at least partially define a one or plurality of flow channels as depicted in FIG. 1.

In the variation set forth in FIG. 3, substrate 32 is pre-coated with metal layer 36 that includes a transition metal catalyst. In one refinement, the metal layer 36 is a transition metal layer. Typically, the transition metal catalyst is disposed over and/or contacts substrate 32. Carbon layer 34 is disposed over and typically contacts metal layer 36 with the metal layer 36 disposed between the carbon layer and the electrically conductive substrate. In a refinement, the metal layer includes a transition metal catalyst Ni, Cu, or Ru. In another refinement, metal layer 36 is a Ni layer, Cu layer, or Ru layer. In still another refinement, metal layer 36 has a thickness from about 2 to 500 nanometers. In a further refinement, metal layer 36 has a thickness from about 10 to 300 nanometers or about 300 nanometers. In a particular refinement, metal layer 36 does not include any chromium and/or titanium.

Advantageously, the fuel cell flow field plates of FIGS. 2 and 3 have low associated contact resistances when incorporated into fuel cells. For example, the contact resistance associated with these bipolar plates is less than 30 mohm cm² at 200 psi load. In a refinement, the contact resistances associated with these bipolar plates is less than 20 mohm cm² at 200 psi load. In another refinement, the contact resistances associated with these bipolar plates is from 5 to 20 mohm cm² at 200 psi load. In still another refinement, the contact resistances associated with these bipolar plates is from 10 to 20 mohm cm² at 200 psi load.

In another embodiment, a method for forming the graphene and/or carbon nanotube layers set forth above on a bipolar plate is provided. The method includes a step of contacting an electrically conductive substrate with a vapor of a C₁₋₁₈ hydrocarbon-containing compound at a temperature from 350° C. to about 600° C. to form a carbon layer. The carbon layer includes from 1 to multiple graphene monolayers. In a refinement, the graphene deposition process is accomplished at pressures from less than or equal to 1 torr to atmospheric pressure. As set forth above, the electrically conductive substrate at least partially defines a plurality of gas flow channels. In one variation, the carbon layer is formed by chemical vapor deposition in which the substrate is contacted with a reaction mixture. Characteristically, the reaction mixture includes the C₁₋₁₈ hydrocarbon-containing compound and reaction products of the C₁₋₁₈ hydrocarbon-containing compound. In a refinement, the reaction mixture further includes a reducing agent such as molecular hydrogen.

In another variation, the carbon layer set forth above is formed by atomic layer deposition (ALD) in which graphene monolayers are formed by one or a plurality of ALD deposition cycles. Characteristically, each ALD deposition cycle produces a monolayer of graphene so that a multilayer graphene coating is constructed layer by layer. An ALD deposition cycle includes a step where an electrically conductive substrate is contacted with the vapor of the C₁₋₁₈ hydrocarbon-containing compound in an ALD reaction chamber. Optionally, the ALD reaction chamber is purged with an inert gas (e.g., argon, helium, nitrogen, etc.) after this step. In a refinement, the ALD deposition cycle further includes a step of contacting the substrate with a reducing agent (e.g., molecular hydrogen) followed again by an optional purging of the ALD reaction chamber with an inert gas.

In some variations of the methods set forth above, the C₁₋₁₈ hydrocarbon containing compound includes a component selected from the group consisting of C₆₋₁₂ aromatic compounds, C₁₋₈ alkanes, C₂₋₈ alkenes, C₂₋₈ alkynes, C₁₋₈ amines and C₁₋₈ alcohols. Examples of C₆₋₁₂ aromatic compounds include, but are not limited to, benzene, toluene, xylenes, and the like. Examples of C₁₋₈ alkanes include, but are not limited to, methane, ethane, propane, butanes, pentanes and the like. Examples of C₂₋₈ alkenes include, but are not limited to, ethylene, propylene, butylenes, and the like. Examples of C₂₋₈ alkynes include acetylene, propyne, butyne, and the like. Examples of C₁₋₈ amines include methyl amine, ethyl amine, propyl amines, dimethyl amine, diethyl amine, and the like. Finally, examples of C₁₋₈ alcohols include methanol, ethanol, propanols, butanols, and the like.

In still other variations of the methods set forth above, the carbon layer is densified. For example, the carbon layer can be densified by a process selected from the group consisting of post-deposition thermal treatment, chemical treatment or plasma treatment, and combinations thereof.

In yet other variations, a metal layer is deposited on the electrically conductive substrate prior to forming the carbon layer. In a refinement, the metal layer includes a transition metal catalyst. In particular, the metal layer includes Ni, Cu, or Ru. In another refinement, metal layer 36 is a Ni layer, Cu layer, or Ru layer. The metal layer can be deposited CVD, ALD, and PVD processes such as evaporation and sputtering. In still another refinement, the metal layer 36 has a thickness from about 50 to 500 nanometers. In a further refinement, the metal layer 36 has a thickness from about 10 to 300 nanometers or about 300 nanometers. In a particular refinement, the metal layer does not include any chromium and/or titanium. In a refinement, the amount of chromium and titanium in the metal layer is less than or equal to, in increasing order of preference, 5.0 weight percent, 2.0 weight percent, 1.0 weight percent, 0.5 weight percent, 0.3 weight percent, 0.1 weight percent, 0.05 weight percent, or 0.01 weight percent or substantially equal to 0 weight percent. Growth on transition metal catalyst layer and lower growth temperatures lead to improved uniformity of the graphene or carbon nanotubes layer. Since the growth of the film is a surface property, the catalyst layer would provide a uniform composition surface irrespective of metal migration in underlying electronically conductive substrate, and in particular, when the substrate is stainless steel. Moreover, the transition metal catalyst layer lowers the range of the carbon layer deposition temperatures.

The following examples illustrate the various embodiments of the present invention. Those skilled in the art will recognize many variations that are within the spirit of the present invention and scope of the claims.

An initial set of CVD depositions at temperatures >650° C. on SS 304L results in non-uniform coating on the stainless steel substrates due to the migration of Cr in the underlying stainless steel. Metal grain rearrangement presents differences in atomic composition, thereby promoting or hindering carbon layer growth, depending on the alloy composition lying underneath.

Test samples are cut in pieces of 2″×2″, cleaned in an ultrasonic bath for 5 minutes each, first in acetone, then in isopropanol. The samples are then dried under a nitrogen gun flow. The dried foils are coated with 300 nm film of nickel using e-beam evaporation. The foils are then inserted in a CVD furnace. After a full power ramp up and a 15 min annealing under hydrogen flow, chemical vapor deposition is performed at 425° C., 450° C., and 475° C. for 60 minutes each, at a C₂H₂ flow rate of 12 sccm diluted in 5 slpm argon.

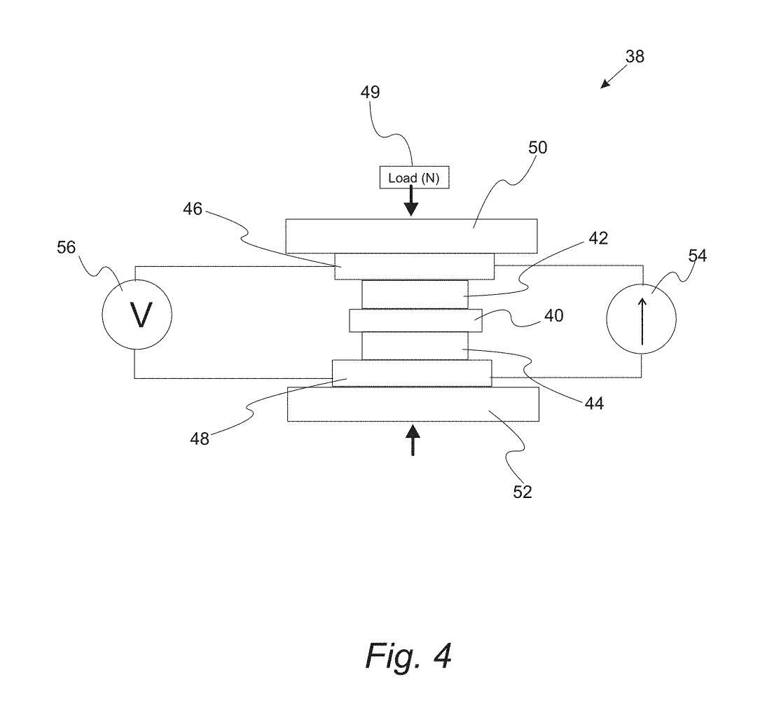

FIG. 4 provides a schematic illustration for an experimental setup for measuring the contact resistance of graphene coated substrates. In contact resistance measurement device 38, sample 40 is positioned between gas diffusion media 42, 44 which are between copper plates 46, 48. A force indicated by load 49 is applied to press plates 50, 52 while a current 54 is provided to the copper plates. Voltage drop 56 is measured such that the contact resistance is provided by the following formula:

Rc=VA_{gdl}/I

where V is the voltage drop, A_{gdl} is the area of the gas diffusion layers, and I is the applied current.

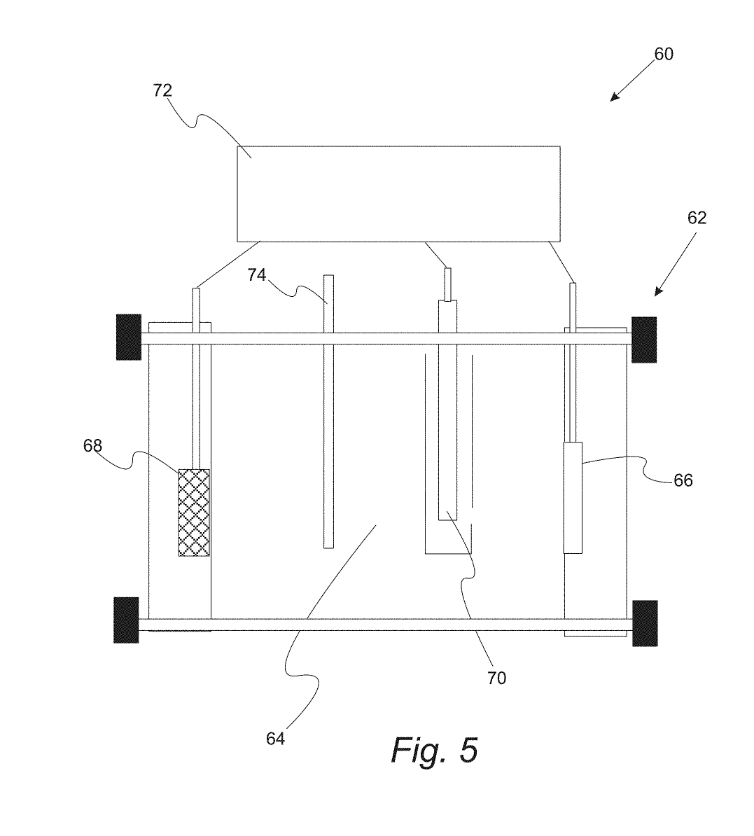

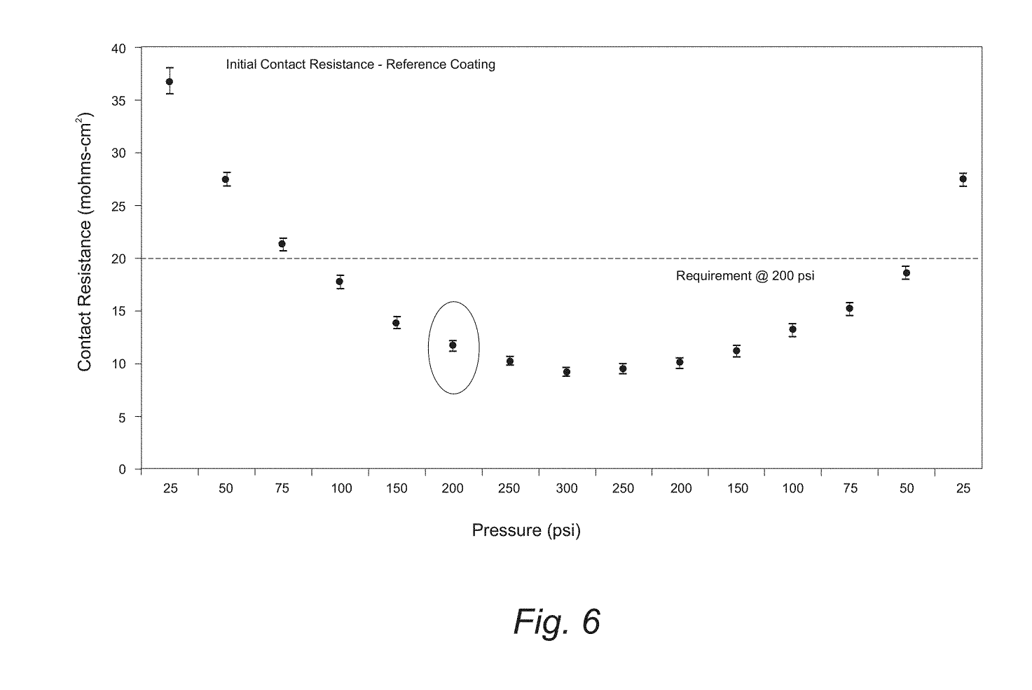

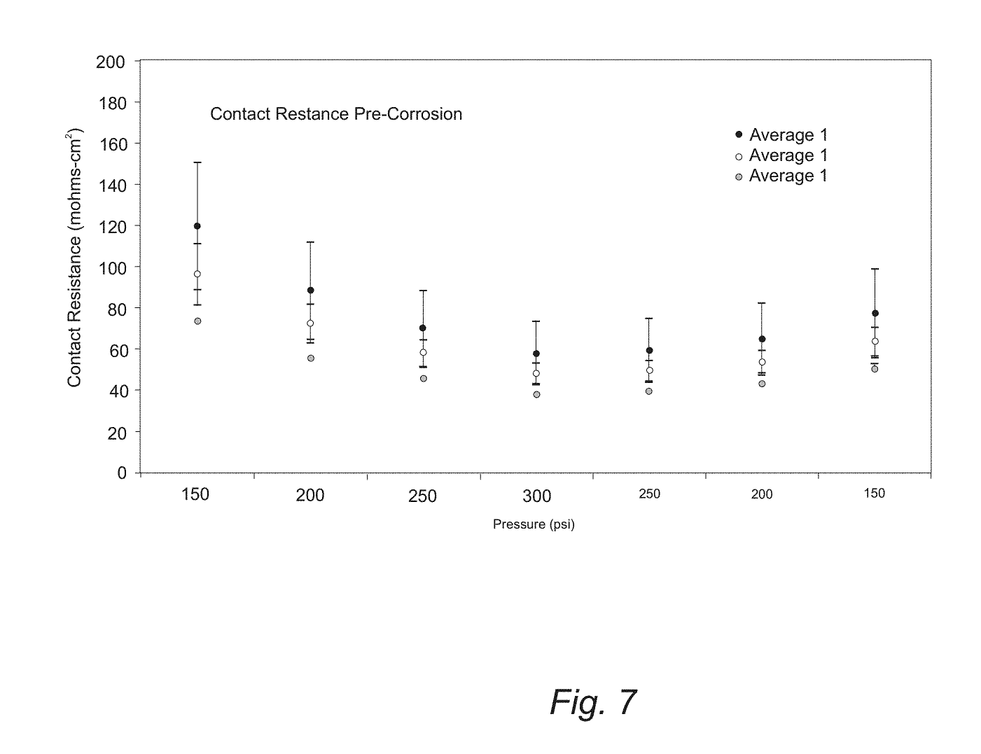

FIG. 5 provides an experimental setup for simulating corrosion. Ex-situ Potentiostatic Durability Experimental Setup 60 includes electrochemical cell 62 which includes electrolyte 64, working electrode 66, counter-electrode 68 (e.g., a platinum mesh), and a reference electrode 70 (e.g., Ag/AgCl). Potentiostat 72 establishes the voltages between the electrodes. The temperature of the electrolyte is measured with thermocouple 74. Typical operation conditions are: operation for over 24 hrs, a temperature of 80° C., and the electrolyte has a pH of 3 (H₂SO₄, 0.1 ppm HF, 0.5M Na₂SO₄), and an applied voltage of 0.6V vs. Ag/AgCl. The step-up is operated with exposure to air (i.e., no purge gas). FIG. 6 provides a plot of the contact resistance versus the applied load for the reference samples as deposited. FIG. 7 provides a plot of the contact resistance versus the applied load for the graphene samples as deposited.

SEM and EDX are performed on each sample at multiple points. Raman mapping is performed using a 633 nm laser to acquire spectra at about 50 points on a nearly 40 μm² area of each sample. The average, variance, and overall range are then evaluated and are shown below. The elemental analysis performed using EDX seems to support the claims that higher chromium content leads to lower carbon synthesis. A steady rise in chromium can be observed in Table 1 as the temperature is raised above 500° C.

TABLE 1
EDX results for samples synthesized
at different growth temperatures.

| Growth | | | |
|---|---|---|---|
| Temperature | EDX Results (% atom content) | | |
| (° C.) | Carbon | Chromium | Nickel |
| 400 | 15.6 | 2.5 | 74.3 |
| 425 | 17.5 | 2.2 | 73.7 |
| 450 | 25 | 2 | 64.8 |
| 475 | 24.9 | 2 | 66 |
| 500 | 7.4 | 3.7 | 80.3 |
| 525 | 11.4 | 4.3 | 73.5 |
| 550 | 6.3 | 4.3 | 78.4 |
| 600 | 6.8 | 9.5 | 64.5 |

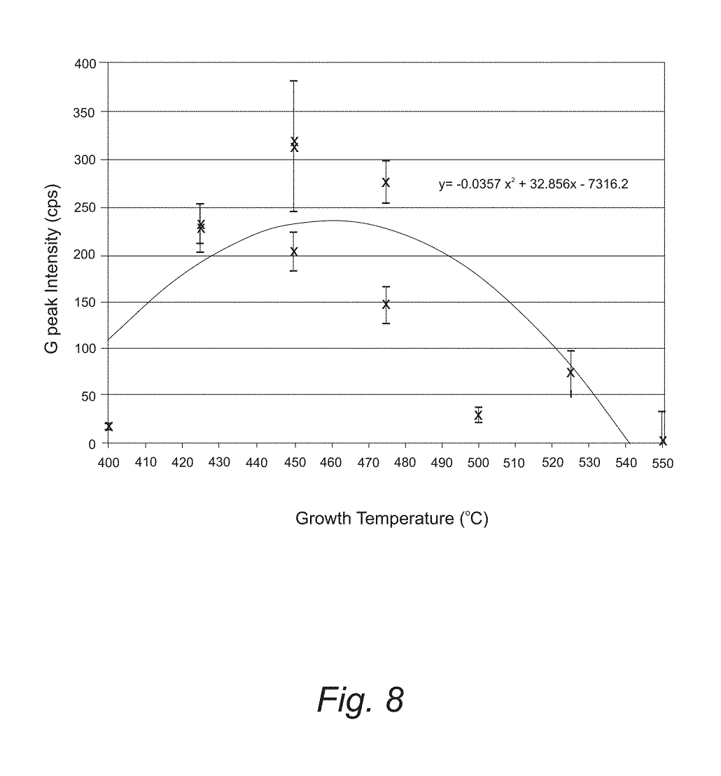

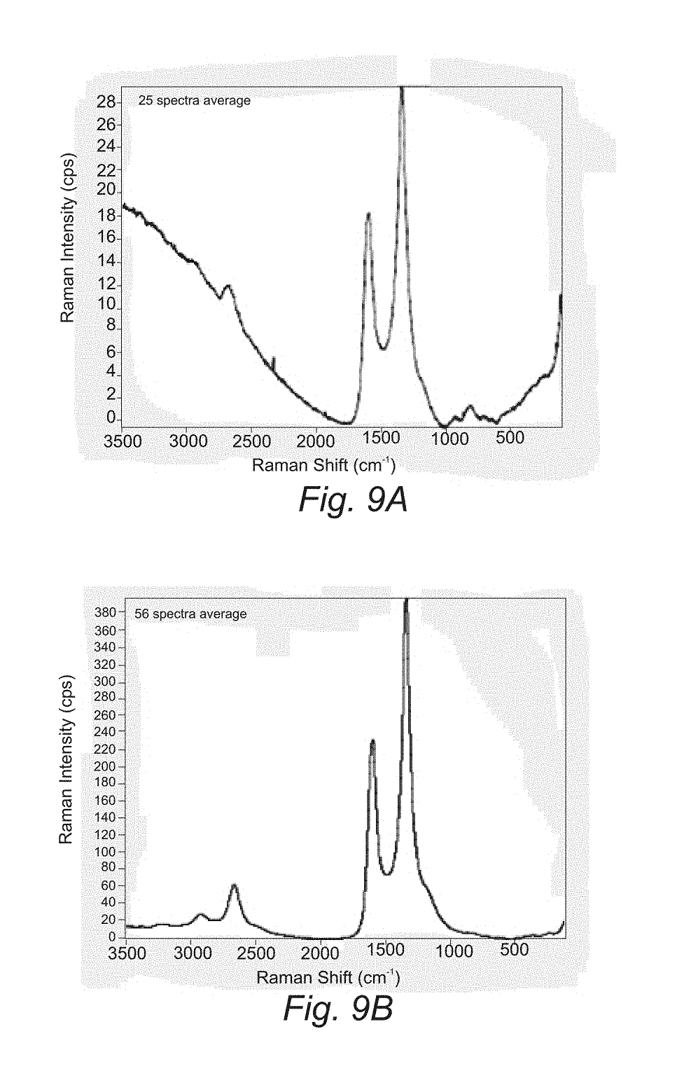

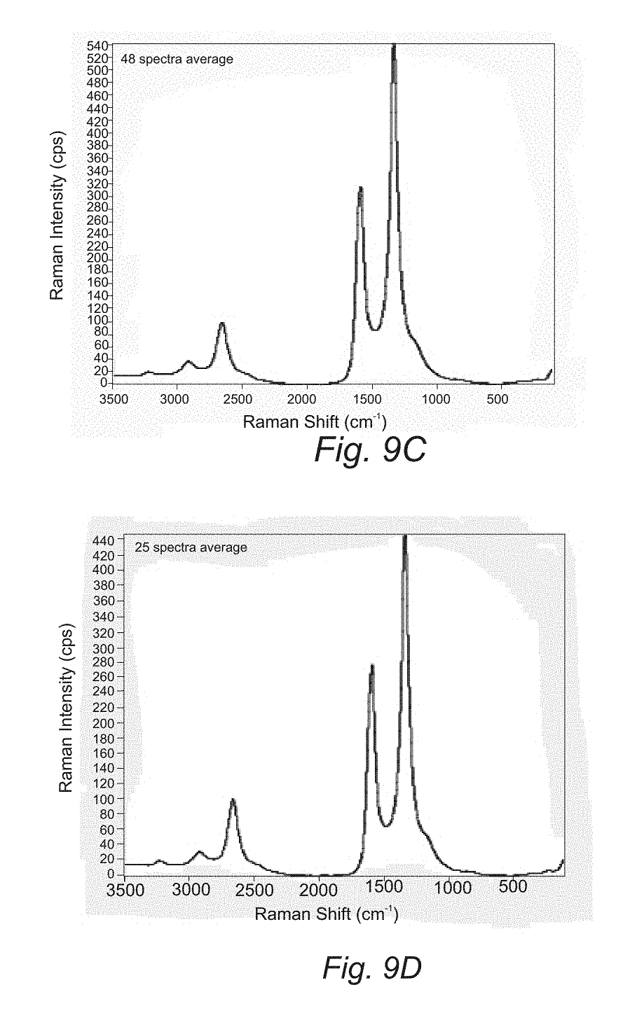

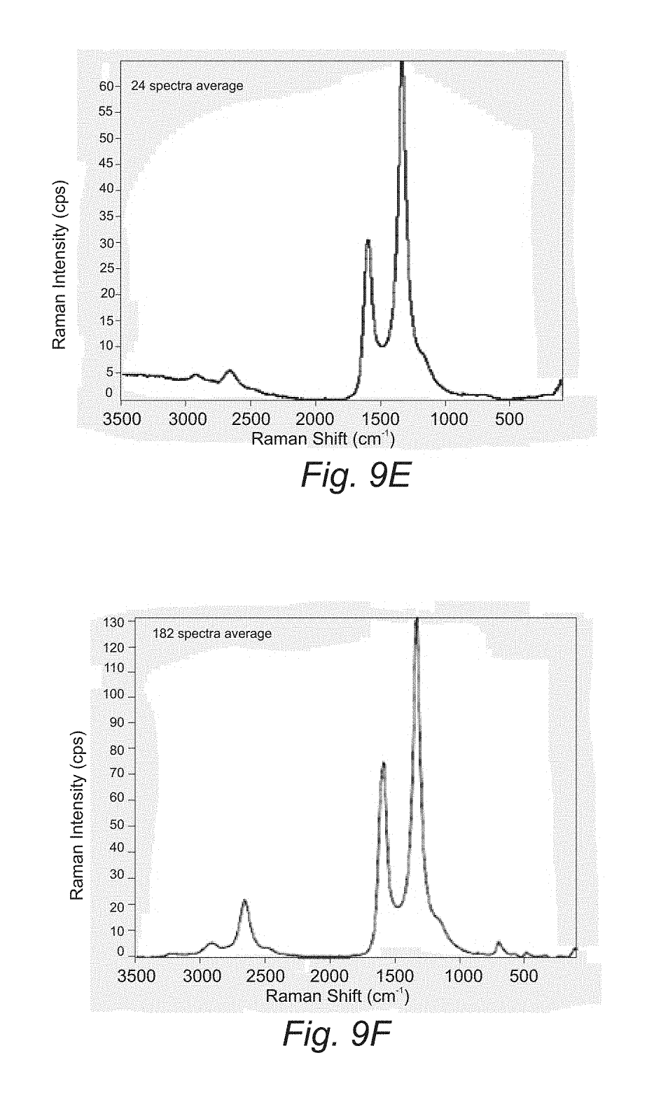

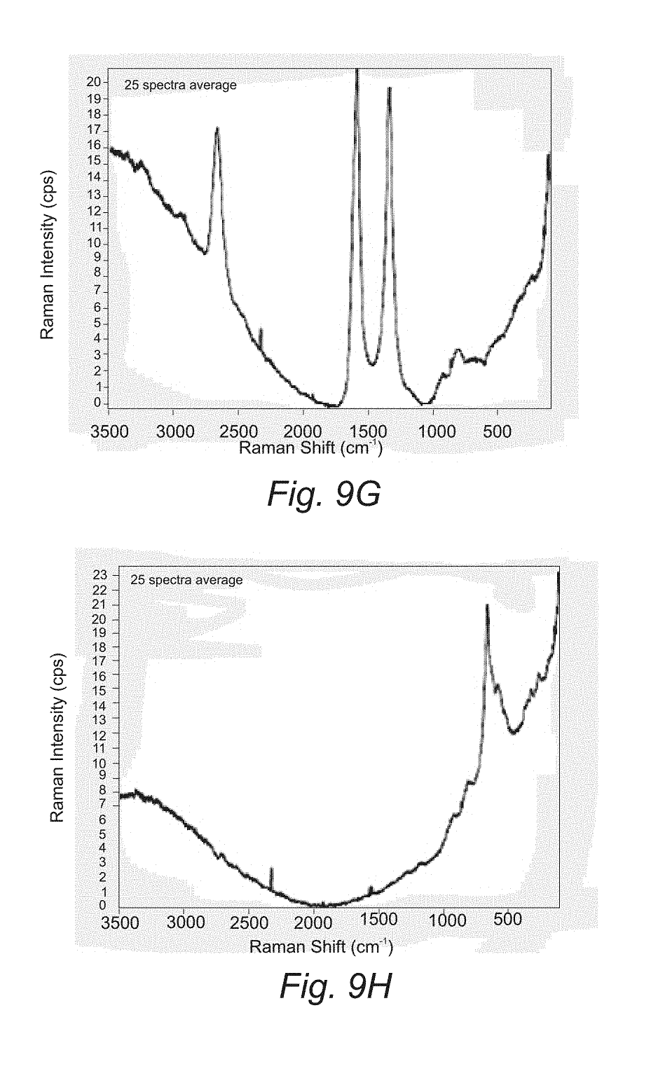

The amount of carbon produced in the graphene coatings is proportional to the intensity of the G peak of the sample's Raman spectra. FIG. 8 provides a plot of the G peak intensity versus temperature for samples synthesized at different CVD growth temperatures with a quadratic curve fitted to the data set and error bars that indicate one standard deviation within the sample area where the Raman map was acquired. The G peak intensity plotted in FIG. 8 also seems to be highest around the 450° C. region, which was therefore selected for performing production runs. As indicated by the Raman spectra in FIGS. 9A-F, coatings synthesized at different growth temperatures indicate that the chromium oxide peaks (at around 700 cm⁻¹) start to appear around 500° C. Similarly, a thick carbon coating can be observed at temperatures around 450° C.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

1.-8. (canceled)

9. A method comprising:
contacting an electrically conductive substrate with a vapor of a C₁₋₁₈ hydrocarbon-containing compound at a temperature from 350° C. to about 600° C. to form a carbon layer, the carbon layer including from 1 to multiple graphene monolayers, the electrically conductive substrate at least partially defining a plurality of gas flow channels.

10. A method comprising of deposition of graphene monolayers at pressure range equal to or less than 1 torr to atmospheric pressure.

11. The method of claim 8 wherein the carbon layer is formed by chemical vapor deposition in which the substrate is contacted with a reaction mixture, the reaction mixture including the C₁₋₁₈ hydrocarbon-containing compound and reaction products of the C₁₋₁₈ hydrocarbon-containing compound.

12. The method of claim 11 wherein the reaction mixture further includes a reducing agent.

13. The method of claim 8 wherein the carbon layer is formed by atomic layer deposition in which graphene monolayers are formed by a deposition cycle including:
a) contacting the substrate with the vapor of the C₁₋₁₈ hydrocarbon containing compound in a reaction chamber; and
b) optionally purging the reaction chamber after step a).

14. The method of claim 13 wherein the deposition cycle further includes;
contacting the substrate with a reducing agent; and
optionally purging the reaction chamber after step c).

15. The method of claim 8 wherein the C₁₋₁₈ hydrocarbon containing compound includes a component selected from the group consisting of C₆₋₁₂ aromatic compounds C₁₋₈ alkanes, C₂₋₈ alkenes, C₂₋₈ alkynes, C₁₋₈ amines and C₁₋₈ alcohols.

16. The method of claim 8 further comprising densifying the carbon layer.

17. The method of claim 16 wherein the carbon layer is densified by a process selected from the group consisting of post-deposition thermal treatment, chemical treatment or plasma treatment, and combinations thereof.

18. The method of claim 8 further comprising forming a metal layer on the electrically conductive substrate prior to forming the carbon layer, the metal layer including a transition metal catalyst.

19. The method of claim 18 wherein the transition metal catalyst layer is Ni, Cu, or Ru layer.

20. The flow field plate of claim 18 wherein the metal layer has a thickness from about 50 to 500 nanometers.
